(19) United States
(12) Patent Application Publication
(10) Pub. No.: US 2017/0198384 A1
(43) Pub. Date: Jul. 13, 2017

(54) DEPOSITION APPARATUS AND DEPOSITION METHOD

(71) Applicant: Sharp Kabushiki Kaisha, Sakai City, Osaka (JP)

(72) Inventors: Yuhki KOBAYASHI, Sakai City (JP); Katsuhiro KIKUCHI, Sakai City (JP); Shinichi KAWATO, Sakai City (JP); Takashi OCHI, Sakai City (JP); Kazuki MATSUNAGA, Sakai City (JP)

(21) Appl. No.: 15/314,629

(22) PCT Filed: Apr. 17, 2015
(86) PCT No.: PCT/JP2015/061829

§ 371 Date: Nov. 29, 2016

(30) Foreign Application Priority Data
May 30, 2014 (JP) 2014-113468

(51) Int. Cl. C23C 14/04; H01L 51/56; C23C 14/24

(52) U.S. Cl. CPC C23C 14/042; C23C 14/24; H01L 51/56

(57) ABSTRACT

A deposition apparatus includes: a first moving apparatus that causes a stepwise change in a relative position between a deposition mask and a substrate in a direction parallel to one surface in a condition in which the deposition mask and the substrate are spaced apart from each other; and a gap adjustment apparatus that, before a start of relative movement between the deposition mask and the substrate by the first moving apparatus, causes relative movement between the deposition mask and the substrate in a direction spacing the deposition mask and the substrate apart and adjusts a gap between the deposition mask and the substrate, and that, when the first moving apparatus has stopped the relative movement between the deposition mask and the substrate, causes relative movement between the deposition mask and the substrate in a direction in which the deposition mask and the substrate approach each other and adjusts the gap between the deposition mask and the substrate.

### TECHNICAL FIELD

The present invention relates to a deposition apparatus and a deposition method.

The subject application claims priority based on the patent application No. 2014-113468 filed in Japan on May 30, 2014, and incorporates by reference herein the content thereof.

### BACKGROUND ART

One proposed method for patterning a substrate using vacuum deposition is that of performing deposition while causing relative movement of a deposition source and deposition mask with respect to a substrate (refer to, for example, Patent Document 1). In this deposition method, because the deposition mask is caused to move in a stepped manner (scanning) relative to the substrate while deposition is done over the entire surface of the substrate, the size of the deposition mask can be made smaller than the substrate. For that reason, it is difficult for the deposition mask to sag, and variation of the film thickness is suppressed.

### PRIOR ART DOCUMENTS

### Patent Document

### [Patent Document 1] Japanese Patent Application Publication No. 2004-349101

### SUMMARY OF THE INVENTION

### Problem to Be Solved by the Invention

With the above-described deposition method, however, in order for the deposition mask that moves relative to the substrate not to come into contact with the substrate, it has been necessary to provide a sufficient distance separating the deposition mask and the substrate. Some of the deposition particles strike the substrate at finite angle with respect to the normal line of the substrate. As a result, if the deposition mask and the substrate are spaced apart, the edges of the deposited film spread farther to the outside than the edges of the aperture patterns of the deposition mask. As a result, there has been the problem of blurring of the deposited pattern.

One aspect of the present invention is made in consideration of the above-noted situation, and has as an object to provide a deposition apparatus and a deposition method capable of suppressing both film thickness variations and deposited pattern blurring.

### Means for Solving the Problems

A deposition apparatus according to a first aspect of the present invention includes: a substrate holder that holds a substrate; a deposition mask that is disposed on one surface side of the substrate; a first moving apparatus that causes a stepwise change in a relative position between the deposition mask and the substrate in a direction parallel to the one surface in a condition in which the deposition mask and the substrate are spaced apart from each other; a gap adjustment apparatus that, before a start of relative movement between the deposition mask and the substrate by the first moving apparatus, causes relative movement between the deposition mask and the substrate in a direction spacing the deposition mask and the substrate apart and adjusts a gap between the deposition mask and the substrate, and that, when the first moving apparatus has stopped the relative movement between the deposition mask and the substrate, causes relative movement between the deposition mask and the substrate in a direction in which the deposition mask and the substrate approach each other and adjusts the gap between the deposition mask and the substrate; and a deposition source that, after the gap adjustment apparatus causes relative movement between the deposition mask and the substrate in a direction in which the deposition mask and the substrate approach each other and adjusts the gap between the deposition mask and the substrate, supplies deposition particles to the one surface of the substrate, through an aperture provided in the deposition mask, to form a film of the deposited particles on the one surface exposed from the aperture.

The deposition apparatus according to the first aspect of the present invention may include: a shutter that, when the deposition mask and the substrate are in relative movement by the first moving apparatus, and when the gap between the deposition mask and the substrate is being adjusted by the gap adjustment apparatus, blocks ejection paths of the deposition particles from the deposition source heading to the aperture.

The deposition apparatus according to the first aspect of the present invention may include: a temperature controlling means that lowers a deposition temperature of the deposition source when the ejection paths of the deposition particles from the deposition source heading toward the aperture are blocked by the shutter.

The deposition apparatus according to the first aspect of the present invention may include: a second moving apparatus that, when the deposition source is supplying the deposition particles to the one surface through the aperture, causes relative movement between the deposition source and the substrate in a direction parallel to the one surface.

In the deposition apparatus according to the first aspect of the present invention, the second moving apparatus may cause relative movement between the deposition source and the substrate so that the deposition source is reciprocally moved when viewed from the substrate.

In the deposition apparatus according to the first aspect of the present invention, the gap adjustment apparatus may rotate the deposition mask about a rotational axis perpendicular to the one surface to align the deposition mask with respect to the substrate.

A deposition method according to a first aspect of the present invention that, by disposing a deposition mask on one surface side of a substrate and, by depositing deposition particles on the one surface through a deposition mask while changing, in a stepped manner, a relative position between the deposition mask and the substrate in a direction parallel to the one surface, sequentially forms a plurality of deposited pattern columns on the one surface, the deposition method including: a first step of fixing relative position of the substrate and the deposition mask, supplying the deposition particles to the one surface through an aperture provided in the deposition mask from a deposition source to form one deposited pattern column on the one surface; a second step of, after completing the first step, causing relative movement between the deposition mask and the substrate in a direction that spaces the deposition mask and the substrate apart to adjust a gap between the deposition mask and the substrate; a third step of causing a change in a relative position between the deposition mask and the substrate in a direction parallel to the one surface in a condition in which the deposition mask and the substrate are spaced apart each other; and a fourth step of, when a relative movement between the deposition mask and the substrate has stopped, causing relative movement between the deposition mask and the substrate in a direction in which the deposition mask and the substrate approach each other to adjust a gap between the deposition mask and the substrate.

In the deposition method according to the first aspect of the present invention, while performing the second step, the third step and the fourth step, ejection paths of the deposition particles from the deposition source heading to the aperture provided in the deposition mask may be blocked.

In the deposition method according to the first aspect of the present invention, the deposition temperature of the deposition source may be lowered while the ejection paths of deposition particles are blocked.

In the deposition method according to the first aspect of the present invention, while performing the first step, relative movement may be caused between the deposition source and the substrate in a direction parallel to the one surface.

In the deposition method according to the first aspect of the present invention, the relative movement may be performed so that the deposition source is reciprocally moved when viewed from the substrate.

In the deposition method according to the first aspect of the present invention, while performing the fourth step, the deposition mask may be rotated about a rotational axis perpendicular to the one surface to align the deposition mask with respect to the substrate.

### Effect of the Invention

According to one aspect of the present invention, it is possible to provide a deposition apparatus and a deposition method capable of suppressing both film thickness variation and deposited pattern blurring.

### BRIEF DESCRIPTIONS OF THE DRAWINGS

FIG. 1 is an oblique view describing a deposition apparatus according to the first embodiment.

FIG. 2 is a schematic representation describing a deposition method according to the first embodiment.

FIG. 3 is a schematic representation describing a deposition method according to the first embodiment.

FIG. 4 is a schematic representation describing a deposition method according to the first embodiment.

FIG. 5 is a schematic representation describing a deposition method according to the first embodiment.

FIG. 6 is a schematic representation describing a deposition method according to the first embodiment.

FIG. 7 is a drawing describing the flow in a deposition method according to the first and the second embodiments.

FIG. 8 is an oblique view describing a deposition apparatus according to the second embodiment.

FIG. 9 is a schematic representation describing a deposition method according to the second embodiment.

FIG. 10 is a schematic representation describing a deposition method according to the second embodiment.

FIG. 11 is a schematic representation describing a deposition method according to the second embodiment.

FIG. 12 is a schematic representation describing a deposition method according to the second embodiment.

FIG. 13 is a schematic representation describing a deposition method according to the second embodiment.

### EMBODIMENTS FOR CARRYING OUT THE INVENTION

### First Embodiment

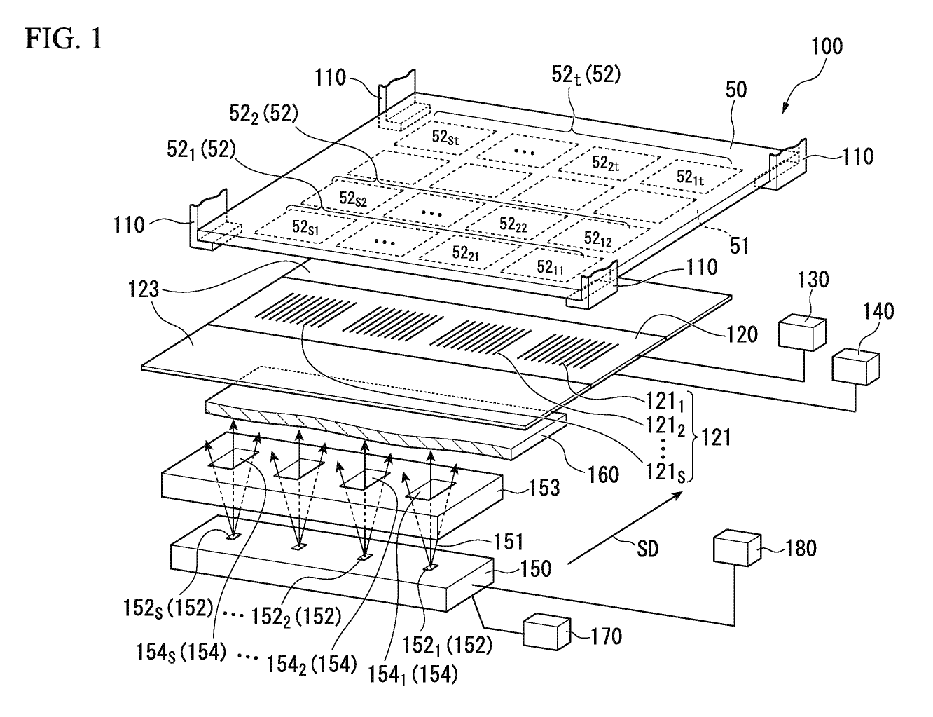

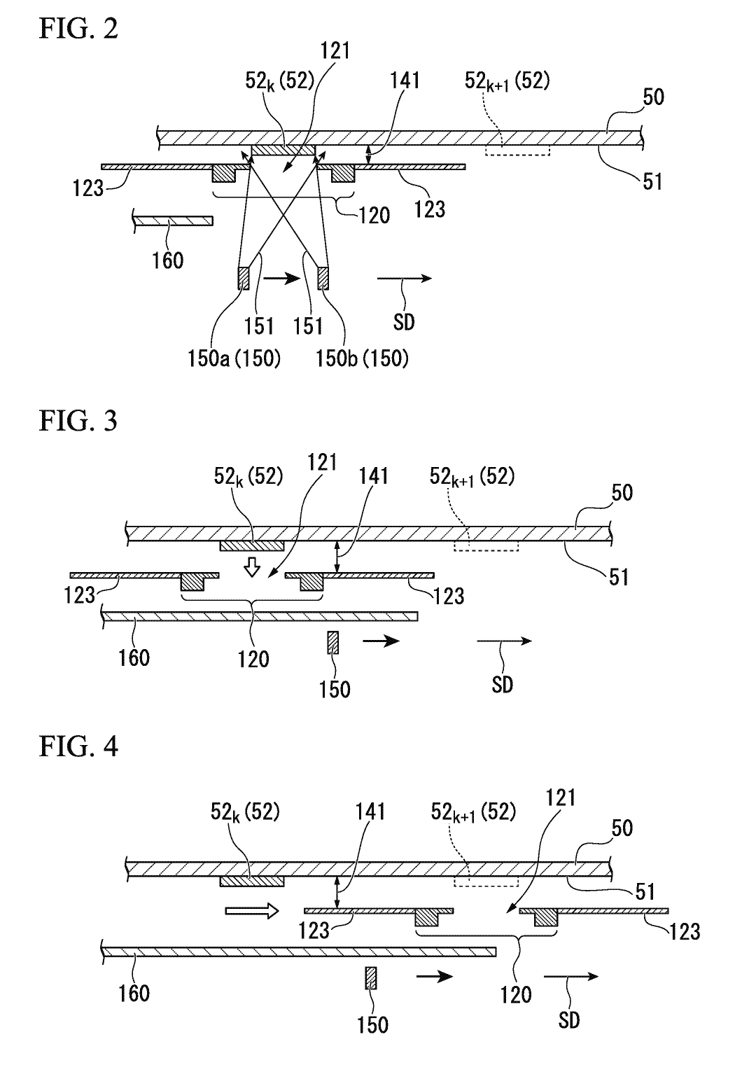

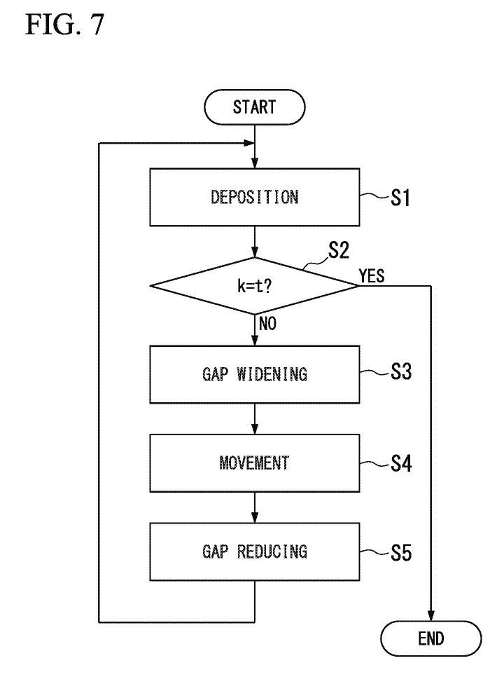

The first embodiment of the present invention will be described below, using FIG. 1 to FIG. 6. FIG. 1 is an oblique view describing a deposition method according to the present embodiment. FIG. 2 to FIG. 6 are schematic representations describing the deposition method according to the present embodiment. FIG. 7 is a drawing describing the flow of the deposition method.

(Deposition Apparatus)

As shown in FIG. 1 a deposition apparatus 100 has a substrate holder 110, a deposition mask 120, a first moving apparatus 130, a gap adjustment apparatus 140, a deposition source 150, a shutter 160, a temperature control means 170, and a second moving apparatus 180.

The deposition apparatus 100 deposits deposition particles on one surface 51 through the deposition mask 120 while moving the deposition mask 120 and the substrate 50 relative to each other in a direction parallel to the one surface 51 of the substrate 50. In the following, the method of performing deposition on the one surface 51 of the substrate 50 while causing relative movement (scanning) between the deposition mask 120 and the substrate 50 will be called scanned deposition, and the direction of the relative movement of the deposition mask 120 with respect to the substrate 50 in the direction SD will be called the scanning direction.

The substrate holder 110 holds the substrate 50 so that the one surface 51 of the substrate 50 faces the deposition source 150. Although the substrate holder 110 is, for example, an arm-shaped member that holds the substrate 50 horizontally, the substrate holder 110 is not restricted to that constitution and, for example, may hold the substrate by an electrostatic chuck mechanism.

A plurality of active areas 52ⱼₖ (where j=1 to s, k=1 to t, s being an integer of 1 or greater and t being an integer of 2 or greater) are arranged in matrix fashion on the one surface 51 of the substrate 50. An active area 54ⱼₖ is an area in which a deposited pattern is formed, this being, for example, a region corresponding to one panel of an organic EL display device. In the following, a one-dimensional arrangement parallel to the scanning direction SD will be called a “row” and the direction perpendicular to the scanning direction SD (hereinafter the “width direction”) will be called a “column.” The number of rows in the arrangement of active areas 54ⱼₖ is s, and the number of columns therein is t. The active areas 54ⱼₖ is an active area disposed in the j-th row and the k-th column. Although FIG. 1 shows the example of s=4 and t=4, s and t are not restricted to these values. All the active areas 52ⱼₖ (k=1 to t) belonging to the same row (j-th row) have the same shape.

In the following, the set of active areas 52ⱼₖ (j=1 to s) belonging to the same column (k-th column) will be called the active area column 52ₖ. The set of all the active areas 52ⱼₖ (j=1 to s, k=1 to t) will sometimes be called the active area group 52.

The deposition mask 120 is disposed on the one surface 51 side of the substrate 50. Apertures 121 are provided in the deposition mask 120. The apertures 121 include, for example, s pattern apertures 121ₗ to 121ₛ disposed in a column in the width direction. The shape of the pattern apertures 121ⱼ (j=1 to s) correspond to the shapes of the deposited patterns to be formed in the active areas 52ⱼₖ (k=1 to t) belonging to the j-th row. Although in FIG. 1, the shape of the pattern apertures 121ⱼ are a plurality of slits parallel to the scanning direction SD, the shapes are not restricted to this, and may be, for example, slots.

The size of the deposition mask 120 in the scanning direction SD enables, for example, the disposition of the pattern apertures 121ⱼ (j=1 to s) of one column, that is, a size enabling disposition of one column of active areas 52ⱼₖ (k=1 to t). Because the deposition mask 120 may be smaller than the substrate 50, even if the substrate 50 grows to be large, it is difficult for sagging of the deposition mask to occur. Thus, variation in the film thickness is suppressed.

Deposition prevention plates 123 are provided on both ends of the deposition mask 120 in the scanning direction SD. The deposition prevention plates 123 block the path of deposition particles flying toward the one surface 51 passing outside of the deposition mask 120. As a result, the only deposition particles reach the one surface 51 through only the apertures 121 of the deposition mask 120, thereby enabling prevention of unwanted deposition of deposition particles that do not contribute to patterning on the one surface 51.

The first moving apparatus 130 causes relative movement of the deposition mask 120 in the scanning direction SD with respect to the substrate 50. The first moving apparatus 130 can be constituted using, for example a drive mechanism such as a ball screw. In the present embodiment, the constitution is one in which the position of the substrate 50 is fixed, and the first moving apparatus 130 moves the position of the deposition mask 120. However, the constitution may be one in which the position of the deposition mask 120 is fixed and the first moving apparatus 130 moves the position of the substrate 50, or one in which the first moving apparatus 130 moves the positions of both the deposition mask 120 and the substrate 50.

So that the deposition mask 120 and the substrate 50 do not come into contact with each other, the first moving apparatus 130 operates with the deposition mask 120 and the substrate 50 spaced apart. The first moving apparatus 130 causes a stepwise change in the relative position between the deposition mask 120 and the substrate 50 in the direction parallel to the one surface 51, so that the plurality of active area columns 52ₖ (k=1 to t) are sequentially opposite the deposition mask 120. This enables patterning of each of the active area columns 52ₖ.

The gap adjustment apparatus 140 causes relative movement between the deposition mask 120 and the substrate 50, in the direction that brings them together or the direction that spaces them apart. This enables adjustment of the gap 141 (refer to FIG. 2) between the deposition mask 120 and the substrate 50.

After the deposition of one active area column 52ₖ is completed, before the deposition mask 120 and substrate 50 are relatively moved, the gap adjustment apparatus 140 spaces apart the deposition mask 120 and the substrate 50. This enables prevention of contact between the deposition mask 120 and the substrate 50 during the relative movement between the deposition mask 120 and the substrate 50.

When the relative movement between the deposition mask 120 and the substrate 50 has stopped, before deposition at the active area column 52ₖ of the movement destination, the gap adjustment apparatus 140 causes the deposition mask 120 and the substrate 50 to mutually approach. This suppresses broadening of the deposited film further to the outside from the edges of the patterns (pattern apertures 121ₗ to 121ₛ) of the apertures 121 of the deposition mask 120, and blurring of the deposited pattern.

The size of the gap 141 (refer to FIG. 2) during the relative movement between the deposition mask 120 and the substrate 50 is preferably 1 mm or greater. Although there is no particular upper limit value, if the gap is made excessively large, the gap adjustment time becomes long and the takt time worsens. The size of the gap 141 during deposition is preferably 0.1 mm to 0.3 mm

The gap adjustment apparatus 140 causes relative movement between the deposition mask 120 and the substrate 50 in the direction perpendicular to the one surface 51. The gap adjustment apparatus 140 is constituted using, for example, a drive mechanism such as a power cylinder mechanism. In the present embodiment, the constitution is one in which the position of the substrate 50 is fixed, and the position of the deposition mask 120 is moved by the gap adjustment apparatus 140. However a constitution may be one in which the position of the deposition mask 120 is fixed, and the position of the substrate 50 is moved by the gap adjustment apparatus 140, or one in which the gap adjustment apparatus 140 moves the positions of both the deposition mask 120 and the substrate 50.

The gap adjustment apparatus 140 includes, for example, a rotating mechanism that rotates the deposition mask 120 about a rotational axis that is orthogonal to the one surface 51. For example, a widely known rotating mechanism used in a rotating stage or the like is used as the rotating mechanism. The gap adjustment apparatus 140 causes the deposition mask 120 to rotate about a rotational axis that is orthogonal to the one surface 51, enabling alignment with respect to the substrate 50.

After the gap adjustment apparatus 140 causes relative movement between the deposition mask 120 and the substrate 50 in the direction in which they approach each other and adjusts the gap 141 (refer to FIG. 2) between the deposition mask 120 and the substrate 50, the deposition source 150 supplies deposition particles to the one surface 51 of the substrate 50, through the apertures 121 provided in the deposition mask 120. This forms a film of deposited particles on the one surface 51 exposed from the apertures 121.

The deposition source 150 includes a nozzle unit 152 that ejects deposition particles. The nozzle unit 152 includes, for example, s nozzles 152₁ to 152ₛ arranged in a column in the width direction. The s nozzles 152₁ to 152ₛ are provided in one-to-one correspondence with the s pattern apertures 121₁ to 121ₛ. When the k-th column, active area column 52ₖ (k=1 to t) is deposited, deposition particles ejected from the j-th row nozzles 121ⱼ (j=1 to s) pass through the j-row pattern apertures 121ⱼ and are deposited on the j-th row active areas 52ⱼₖ. By doing this, a deposited pattern corresponding to the shapes of the j-th row pattern apertures 121ⱼ is formed in active areas 52ⱼₖ of the j-th row.

In the following, the regions that join the nozzle unit 152 of the deposition source 150 and the apertures 121 of the deposition mask 120 will be called the ejection paths 151. An ejection path 151 is a set of paths through which the individual deposition particles fly. The flying paths of the individual deposition particles depart from the nozzle part 152 of the deposition source 150 and reach a point within an aperture 121 of the deposition mask 120. In the case in which the deposition source 150 has s nozzles 152₁ to 152ₛ, and the deposition mask has s pattern apertures 121₁ to 121ₛ corresponding thereto, such as in the present embodiment, the ejection paths 151 are s conical regions. Each of the conical regions has one nozzle 152ⱼ at its vertex and a pattern 121ⱼ at its base (j=1 to s).

A deposition particle limiter 153, for example, may be provided on the side of the deposition source 150 opposite the deposition mask 120. The deposition particle limiter 153 is fixed in the perpendicular direction and horizontal direction with respect to the deposition source 150. A plurality of through holes 154, through which deposition particles pass, are provided in the deposition particle limiter 153. For example, the deposition particle limiter 153 includes s through holes 154₁ to 154ₛ disposed in one column in the width direction. The s through holes 154₁ to 154ₛ are provided in one-to-one correspondence with the s nozzles 152₁ to 152ₛ. By doing this, of the deposition particles that are ejected from each of the nozzles 152₁ to 152ₛ at a wide angle direction, only deposition particles that have passed through the through holes 154₁ to 154ₛ reach the deposition mask 120, thereby increasing the directivity of the ejection of the deposition particles ejection direction.

The shutter 160 is a plate-shaped member that can be inserted between the deposition mask 120 and the deposition source 150. When the deposition mask 120 and the substrate 50 are in relative movement by the first moving apparatus 130, and when the gap 141 (refer to FIG. 2) between the deposition mask 120 and the substrate 50 is being adjusted by the gap adjustment apparatus 140, the shutter 160 blocks ejection paths 151 of the deposition particles from the deposition source 150 heading to the apertures 121. This enables deposition onto the substrate 50 only when in the condition in which the deposition mask 120 and the substrate 50 are in mutual proximity As a result, it is possible to suppress blurring of the deposited pattern. Also, although in FIG. 1 the shutter 160 is provided between the deposition mask 120 and the deposition particle limiter 153, it may be provided between the deposition particle limiter 153 and the nozzles 152.

The length of the shutter 160 in the scanning direction SD is, for example, sufficiently long to enabling covering of all of the active area columns 52₁ to 52ₜ from the 1st column to the t-th column. During the adjustment of the gap 141 (refer to FIG. 2) with the active area columns 52ₖ (k=1 to t) of the k-th row opposite the apertures 121 of the deposition mask 120, the shutter 160 is inserted up to the position to a position at which it covers the active area row 52ₖ of the k-th row. This blocks the ejection path 151 of the deposition particles heading toward the active area row 52ₖ of the k-th row.

The temperature controlling means 170 controls the temperature of the deposition source 150. The temperature control means 170, for example, lowers the deposition temperature of the deposition source 150 when the ejection paths 151 of deposition particles from the deposition source 150 heading toward the apertures 121 are blocked by the shutter 160. This suppresses the flying of deposition particles and enables suppression of unnecessary consumption of deposition material during a time when deposition is not done onto the substrate 50.

The second moving apparatus 180 causes relative movement of the deposition source 150 with respect to the substrate 50 in the scanning direction SD. For example, the second moving apparatus 180 causes relative movement between the deposition source 150 and the substrate 50 using a drive mechanism such as a ball screw. In the present embodiment, the constitution is one in which the position of the substrate 50 is fixed, and the position of the deposition source 150 is moved by the second moving apparatus 180.

When the deposition source 150 is supplying the deposition particles to the one surface 51 through the apertures 121, the second moving apparatus 180 causes relative movement between the deposition source 150 and the substrate 50 in the direction parallel to the one surface 51. This suppresses variation in film thickness due to the distribution of deposition speed of the deposition particles, thereby enabling the film thickness to be made uniform.

(Deposition Method)

The deposition method according to the present embodiment will now be described, using FIG. 2 to FIG. 7. As an expediency in FIG. 2 to FIG. 6, the substrate holder 110, the first moving apparatus 130, the gap adjustment apparatus 140, the temperature control means 170, and the second moving apparatus 180 are omitted.

By disposing the deposition mask 120 on the one surface 51 side of the substrate 50 and depositing deposition particles on the one surface 51 through the deposition mask 120 while changing, in a stepped manner, the relative position between the deposition mask 120 and the substrate 50 in the direction parallel to the one surface S1, the deposition method according to the present embodiment sequentially forms a plurality of deposited pattern columns on the one surface 51. As shown in FIG. 7, in the deposition method according to the present embodiment, a deposition step (first step) S1, a determination step S2, a gap widening step (second step) S3, a movement step (third step) S4, and a gap reducing step (fourth step) S5 are sequentially performed.

(Deposition Step S1 with Respect to the k-th Column Active Area Column)

First, as shown in FIG. 2, the relative position of the substrate 50 and the deposition mask 120 are fixed, and one deposited pattern column is formed on the one surface 51 of the substrate 50. FIG. 2 shows an example in which the k-th column, active column 52ₖ (k=1 to t−1) deposited pattern column is formed. One deposited pattern column includes s deposited patterns. The s deposited patterns are films of deposition particles to be deposited through the s pattern apertures 121₁ to 121ₛ. While the deposition is being performed, the relative position between the deposition mask 120 and the substrate 50 is fixed. While the deposition is being performed, the size of the gap 141 between the deposition mask 120 and the substrate 50 is set sufficiently small. This enables suppression of blurring of the edges of the deposited pattern.

When the deposition with respect to the k-th column, active area column 52ₖ is started, the deposition source 150 is positioned at the deposition starting position 150a with respect to the k-th column, active area column 52ₖ. At the time at which the deposition with respect to the k-th column, active area column 52ₖ, is started, the shutter 160 is pulled out from the space between the deposition mask 120 and the deposition source 150. This opens up the ejection paths from the deposition source 150 that reach the apertures 121 of the deposition mask 120. As a result, the deposition of the k-th column, active area column 52ₖ, starts.

During the deposition with respect to the k-th column, active area column 52ₖ, the second moving apparatus 180 (refer to FIG. 1) causes relative movement of the deposition source 150 with respect to the substrate 50 in the scanning direction SD, from the deposition starting position 150a with respect to the k-th column, active area column 52ₖ, up to the deposition ending position 150b with respect to the k-th column, active area column 52ₖ.

If deposition is done with the deposition source 150 fixed with respect to the substrate 50, film thickness variation occurs. Because the incidence angle of the deposition particles is distributed over the one surface 51 of the substrate 50, this film thickness variation is due also to the deposition particle deposition rate having a distribution over the one surface 51. In contrast, in the present embodiment, during deposition, the deposition source 150 moves relative to the substrate 50 in the scanning direction SD. As a result of this, during the deposition with respect to the k-th column, active area column 52ₖ, deposition is done of deposition particles reaching the deposition ending position 150b from the deposition starting position 150a from various directions. As a result, the film thickness variation is suppressed, and it is possible to make the film thickness uniform.

When the deposition with respect to the k-th column, active area column 52ₖ, ends, the shutter 160 is inserted into the space between the deposition mask 120 and the deposition source 150 positioned at the deposition ending position 150b. This closes the ejection paths from the deposition source 150 to the apertures 121 of the deposition mask 120. As a result, the deposition step S1 with respect to the k-th column, active area column 52ₖ, ends.

(Determination Step S2)

As shown in FIG. 7, at the point at which the deposition step S1 ends, if the formation of the deposited pattern columns with respect to the all of the active area columns 52ₖ (k=1 to t) from the 1st to the t-th column has been completed, the entire deposition process is ended. If that is not the case, processing proceeds to the gap widening step S3.

(Gap Widening Step S3)

Next, as shown in FIG. 3, the gap adjustment apparatus 140 (refer to FIG. 1) spaces apart the deposition mask 120 and the substrate 50. At the point at which the gap 141 between the deposition mask 120 and the substrate 50 has become sufficiently large, the gap adjustment apparatus 140 stops the relative movement between the deposition mask 120 and the substrate 50. By setting a sufficiently large gap 141, it is possible to prevent contact between the deposition mask 120 and the substrate 50 during the time in which the deposition mask 120 is moving relative to the substrate 50 in the scanning direction SD in the movement step S4, which will be described later.

During the time when the gap adjustment apparatus 140 spaces the deposition mask 120 and the substrate 50 apart, as shown in FIG. 3, the second moving apparatus 180 (refer to FIG. 1) may move the deposition source 150 relative to the substrate 50 in the scanning direction SD. In this case, the shutter 160 moves relatively with respect to the substrate 50 in the scanning direction SD, tracking to the deposition source 150, so that the ejection paths from the deposition source 150 to the apertures 121 of the deposition mask 120 continue to be blocked.

(Movement Step S4)

Next, as shown in FIG. 4, the first moving apparatus 130 (refer to FIG. 1) causes movement of the deposition mask 120 relative to the substrate 50 in the scanning direction SD from the position at which the apertures 121 are opposite to the k-th column, active area column 52ₖ, to the position at which they are opposite the (k+1)th column, active area column 52ₖ₊₁. When the deposition mask 120 reaches the position at which the apertures 121 are opposite the (k+1)th column, active area column 52ₖ₊₁, the first moving apparatus 130 stops the relative movement between the deposition mask 120 and the substrate 50.

During the relative movement of the deposition mask 120 with respect to the substrate 50 in the scanning direction SD, as shown in FIG. 4, the second moving apparatus 180 (refer to FIG. 1) may move the deposition source 150 relative to the substrate 50 in the scanning direction SD, in which case the shutter 160 moves relative to the substrate 50 in the scanning direction SD, so that the ejection paths from the deposition source 150 to the apertures 121 of the deposition mask 120 continue to be blocked.

(Gap Reducing Step S5)

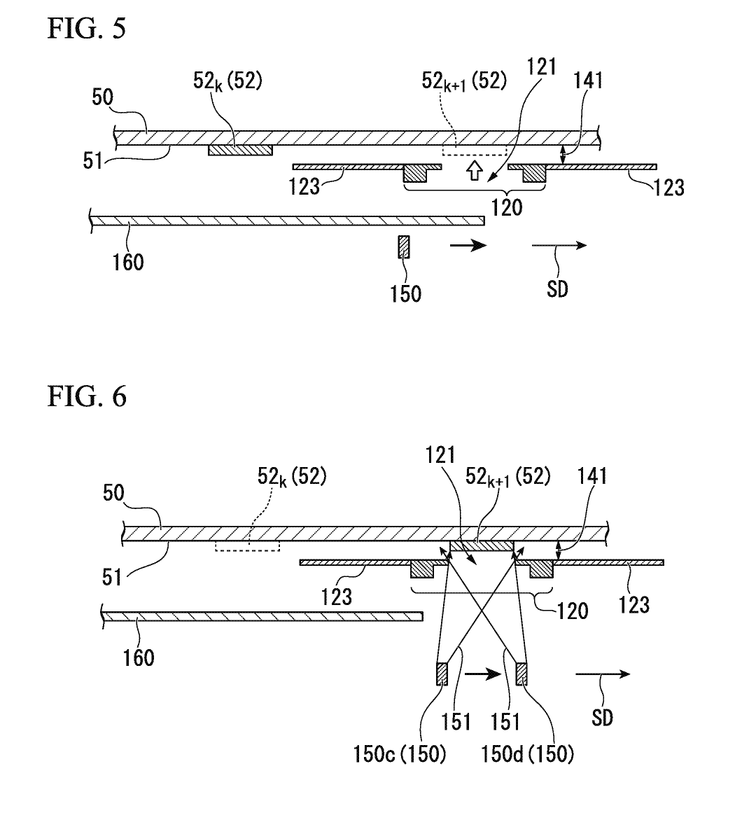

Next, as shown in FIG. 5, the gap adjustment apparatus 140 (refer to FIG. 1) causes the deposition mask 120 and the substrate 50 to approach each other. At the point at which the gap 141 between the deposition mask 120 and the substrate 50 has become sufficiently small, the gap adjustment apparatus 140 stops the relative movement between the deposition mask 120 and the substrate 50. By setting the gap 141 sufficiently small, it is possible to suppress blurring of the edges of the deposited pattern.

If the gap adjustment apparatus 140 has a rotating mechanism, in the gap reducing step S5, the deposition mask 120 may be rotated about a rotational axis perpendicular to the one surface 51 to perform alignment with respect to the substrate 50.

During the time when the deposition mask 120 and the substrate 50 are in mutual proximity, as shown in FIG. 5, the second moving apparatus 180 (refer to FIG. 1) may cause relative movement of the deposition source 150 with respect to the substrate 50 in the scanning direction SD, in which case the shutter 160 moves relatively with respect to the substrate 50 in the scanning direction SD, tracking to the deposition source 150, so that the ejection paths from the deposition source 150 to the apertures 121 of the deposition mask 120 continue to be blocked.

Until the time that the deposition with respect to the (k+l)th column, active area column 52ₖ₊₁, starts, the second moving apparatus 180 causes relative movement of the deposition source 150 with respect to the substrate 50 in the scanning direction SD and causes the deposition source 150 to reach the deposition starting position 150c with respect to the (k+1)th column, active area column 52k₊₁.

(Deposition Step S1 with Respect to the (k+1)th Active Area Column)

Next, as shown in FIG. 6, deposition is performed with respect to the (k+1)th column, active area column 52ₖ₊₁. At the time the deposition with respect to the (k+1)th column, active area column 52 starts, the deposition source 150 is positioned at the deposition starting position 150c with respect to (k+1)th column, active area column 52ₖ₊₁. At the time the deposition with respect to the (k+1)th column, active area column 52ₖ₊₁, starts, the shutter 160 is pulled out from the space between the deposition mask 120 and the deposition source 150. This opens up the ejection paths from the deposition source 150 to the apertures 121 of the deposition mask 120. As a result, the deposition of the (k+1)th column, active area column 52ₖ₊₁, starts.

During the deposition with respect to the (k+1)th column, active area column 52ₖ₊₁, the second moving apparatus 180 (refer to FIG. 1) causes relative movement of the deposition source 150 from the deposition starting position 150c with respect to the (k+1)th column, active area column 52ₖ₊₁, to the deposition ending position 150d with respect to the (k+1)th column, active area column 52ₖ₊₁.

After that, in the same manner, deposition is performed from the 1st column, active area column 52₁, to the t-th column, active area column 52ₜ. This completes the deposition of the entire region of the active area group 52.

The first embodiment is described above. Although in the above-described gap widening step S3 to the gap reducing step S5, the deposition source 150 continues to move in the scanning direction SD, this is not a restriction. For example, at the point in time at which the deposition with respect to the k-th column, active area column 52ₖ, has ended, after the deposition source 150 is made to stop at the deposition ending position 150b with respect to the k-th column, active area column 52ₖ, the deposition mask 120 being spaced apart from the substrate 50 and being moved in the scanning direction SD of the deposition mask 120 and, after coming into proximity with the substrate 50, the deposition source 150 may be moved from the deposition ending position 150b with respect to the kth column, active area column 52ₖ, to the deposition starting position 150c with respect to the (k+1)th column, active area column 52₍ₖ₊₁₎.

Also, for example, if the active area of the substrate 50 has rotational symmetry about a rotational axis perpendicular to the one surface 51 and also if the number of active area columns t is even, the deposition source 150 is first moved in the scanning direction SD with respect to the 1st to (t/2)th columns, active area columns 52₁ to 524_{t/2}. Next, during the change of the active area column from the 1st to (t/2)th columns to the (t/2+1)th to t-th columns, the substrate 50 is changed in disposition by a 180° rotation about the rotational axis perpendicular to the one surface 51. Finally, the deposition source 150 is moved in the direction opposite to the scanning direction SD from the (t/2+1)th to t-th column, active area columns 52_{t/2+1} to 52ₜ. This enables the halving of the range of movement of the deposition source 150. As a result, the size of the second moving apparatus 180 can be reduced and the equipment cost can be reduced.

In the present embodiment, while deposition is being done, the temperature control means 170 may be used to lower the temperature of the deposition source 150. This enables suppression of unnecessary consumption of material.

### Second Embodiment

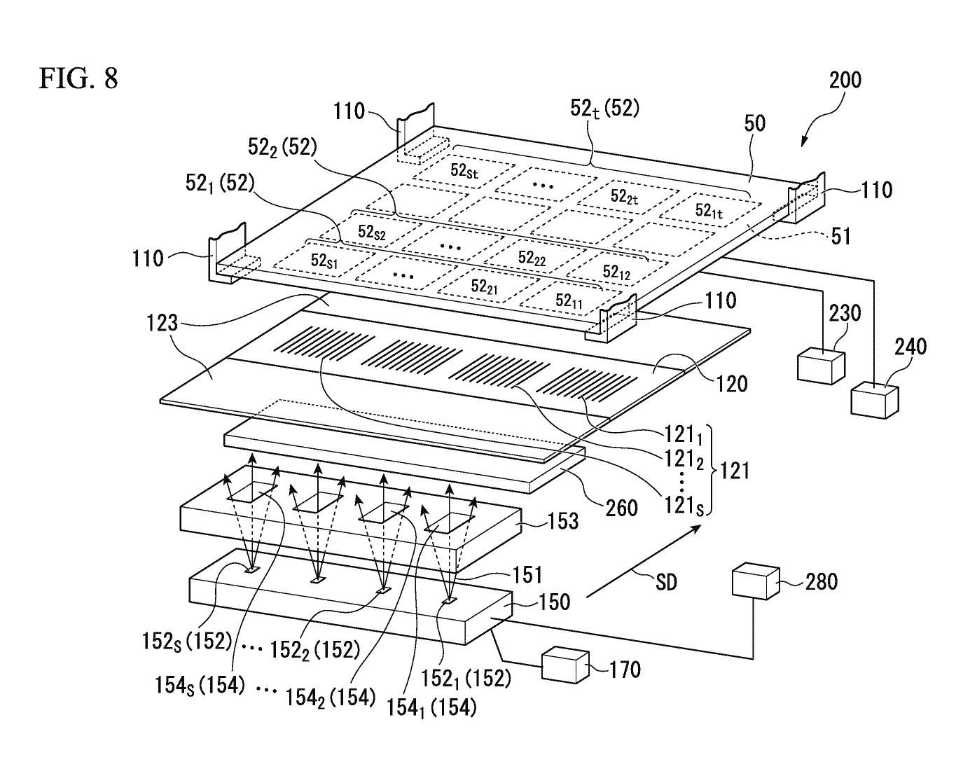

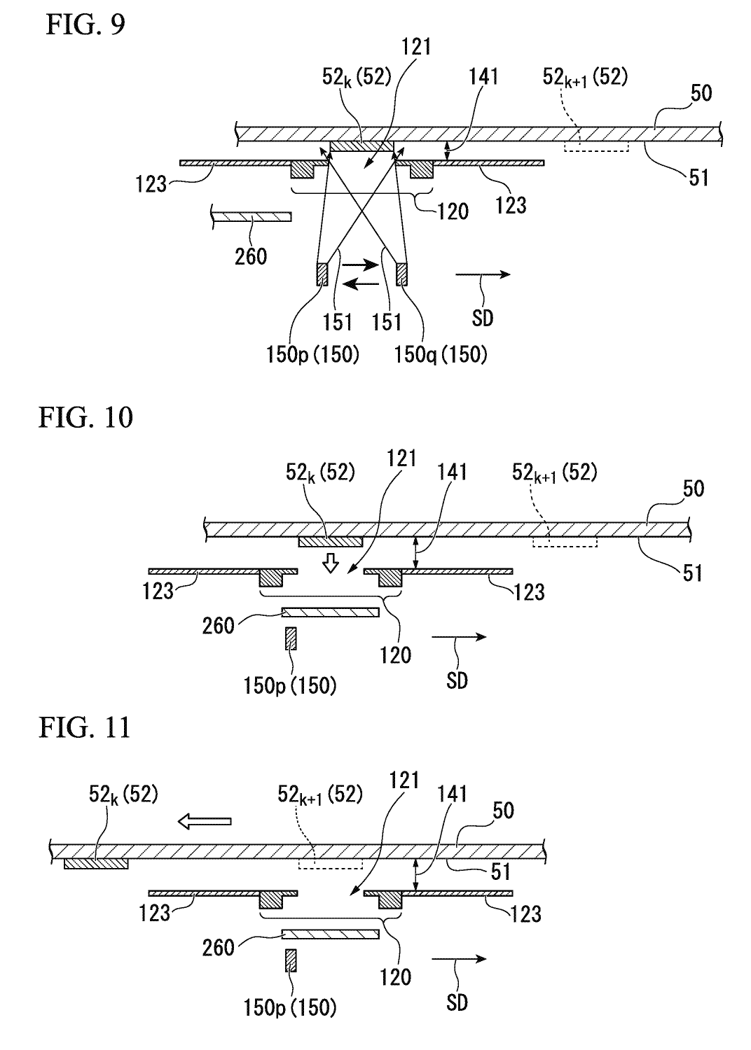

The second embodiment of the present invention will now be described, using FIG. 7 to FIG. 13. FIG. 8 is an oblique view describing the deposition apparatus according to the present embodiment. FIG. 9 to FIG. 13 are schematic representations of the deposition method according to the present embodiment.

In the present embodiment, a first moving apparatus 230 causes relative movement of the substrate 50 with respect to the deposition mask 120. A gap adjustment apparatus 240 brings the substrate 50 into proximity with or spaces it apart from the deposition mask 120. A second moving apparatus 280 causes reciprocating movement of the deposition source 150 with respect to the deposition mask 120. The length of the shutter 260 is shorter in the scanning direction SD. These are the major differences of the present embodiment from the first embodiment.

(Deposition Apparatus)

A deposition apparatus 200 according to the present embodiment will now be described, using FIG. 8. In the following, constituent elements that are in common with those shown in FIG. 1 to FIG. 6 are assigned the same reference symbols and the descriptions thereof are omitted.

The deposition apparatus 200 includes a substrate holder 110, a deposition mask 120, a first moving apparatus 230, a gap adjustment apparatus 240, a deposition source 150, a shutter 260, a temperature control means 170, and a second moving apparatus 280.

The first moving apparatus 230 causes relative movement of the substrate 50 with respect to the deposition mask 120, in the direction reverse from the scanning direction SD. The first moving apparatus 230 is constituted using, for example, a drive mechanism such as a ball screw. In the present embodiment, the constitution is one in which the position of the deposition mask 120 is fixed, and the first moving apparatus 230 moves the position of the substrate 50. The movement of the substrate 50, for example, is done by fixing the substrate 50 to the substrate holder 110 and moving the substrate 50 together with the substrate holder 110.

So that the deposition mask 120 and the substrate 50 do not come into contact, the first moving apparatus 230 operates with the deposition mask 120 and the substrate 50 spaced apart. The first moving apparatus 230 causes a stepwise change in the relative position between the deposition mask 120 and the substrate 50, so that the plurality of active area columns 52ₖ (k=1 to t) are sequentially opposite the deposition mask 120. This enables individual patterning of each of the active area columns 52ₖ.

The gap adjustment apparatus 240 causes relative movement between the deposition mask 120 and the substrate 50, in the direction that brings them together or the direction that spaces them apart. This enables adjustment of the gap 141 (refer to FIG. 9) between the deposition mask 120 and the substrate 50.

After the deposition of one active area column 52ₖ is completed, before the deposition mask 120 and substrate 50 are relatively moved, the gap adjustment apparatus 240 gap adjustment apparatus 240 space the deposition mask 120 and the substrate 50 apart. This enables prevention of contact between the deposition mask 120 and the substrate 50 during the relative movement between the deposition mask 120 and the substrate 50.

When the relative movement between the deposition mask 120 and the substrate 50 has stopped, before deposition at the active area column 52ₖ of the movement destination, the gap adjustment apparatus 240 causes the deposition mask 120 and the substrate 50 to come into mutual proximity This suppresses broadening of the deposited film further to the outside from the edges of the patterns (pattern apertures 121₁ to 121ₛ) of the apertures 121 of the deposition mask 120, and suppresses blurring of the deposited pattern.

The size of the gap 141 (refer to FIG. 9) during the relative movement between the deposition mask 120 and the substrate 50 is preferably 1 mm or greater. Although there is no particular upper limit, if the gap is made excessively large, the gap adjustment time becomes long and the takt time worsens. The size of the gap 141 during deposition is preferably 0.1 mm to 0.3 mm.

The gap adjustment apparatus 240 causes relative movement between the deposition mask 120 and the substrate 50 in the direction perpendicular to the one surface 51. The gap adjustment apparatus 240 is constituted using, for example, a drive mechanism such as a power cylinder mechanism. In the present embodiment, the constitution is one in which the position of the deposition mask 120 is fixed, and the position of the substrate 50 is moved by the gap adjustment apparatus 240. However a constitution may be one in which the position of the substrate 50 is fixed, and the position of the deposition mask 120 is moved by the gap adjustment apparatus 240, or one in which the gap adjustment apparatus 240 moves the positions of both the deposition mask 120 and the substrate 50.

The gap adjustment apparatus 240 includes, for example, a rotating mechanism that rotates the deposition mask 120 about a rotational axis that is orthogonal to the one surface 51. For example, a rotating mechanism such as used in a rotating stage or the like is used. The gap adjustment apparatus 140 causes the deposition mask 120 to rotate about a rotational axis that is orthogonal to the one surface 51, enabling alignment with respect to the substrate 50.

The shutter 260 is a plate-shaped member that can be inserted between the deposition mask 120 and the deposition source 150. When the deposition mask 120 and the substrate 50 are in relative movement by the first moving apparatus 230, and when the gap 141 (refer to FIG. 9) between the deposition mask 120 and the substrate 50 is being adjusted by the gap adjustment apparatus 240, the shutter 260 blocks the ejection paths 151 of deposition particles from the deposition source 150 heading to the apertures 121. This enables deposition onto the substrate 50 only when in the condition in which the deposition mask 120 and the substrate 50 are in mutual proximity As a result, it is possible to suppress blurring of the deposited pattern.

During deposition, the second moving apparatus 280 causes reciprocating movement of the deposition source 150 parallel to the substrate 50, in the scanning direction SD. The second moving apparatus 280 uses, for example, a drive mechanism such as a ball screw and causes relative movement between the deposition source 150 and the deposition mask 120. In the present embodiment, the constitution is such that, during deposition, the substrate 50 is stopped and the position of the deposition source 150 is moved by the second moving apparatus 180.

When the deposition source 150 is supplying deposition particles to the one surface 51 through the apertures 121, the second moving apparatus 280 causes relative movement between the deposition source 150 and the substrate 50 in the direction parallel to the one surface 51. This suppresses variation in film thickness due to the distribution of deposition speed of the deposition particles, thereby enabling the film thickness to be made uniform.

In the present embodiment, the constitution is such that the position of the deposition mask 120 is fixed and the position of the substrate 50 is moved by the first movement apparatus 230. For that reason, the deposition source 150 can be reciprocally moved only in the vicinity of positions opposing the fixed apertures 121. As a result, it is possible to reduce the cost of driving the deposition source 150.

In the present embodiment, because the position of the deposition mask 120 is fixed, it is sufficient that the shutter 260 have a length in the scanning direction SD to the extent that it enables covering of one column within the active area group 52 of the substrate 50. As a result, the shutter 260 can be made lighter, so that it is possible to prevent sag of the shutter 260 and reduce the cost of driving.

(Deposition Method)

The deposition method according to the present embodiment will now be described, using FIG. 7 and FIG. 9 to FIG. 13. As an expediency in FIG. 9 to FIG. 12, the substrate holder 110, the first moving apparatus 230, the gap adjustment apparatus 240, the temperature control means 170, and the second moving apparatus 280 are omitted.

By disposing the deposition mask 120 on the one surface 51 side of the substrate 50 and by depositing deposition particles on the one surface 51 through the deposition mask 120 while changing in a stepwise manner the relative position between the deposition mask 120 and the substrate 50 in the direction parallel to the one surface 51, the deposition method according to the present embodiment sequentially forms a plurality of deposited pattern columns on the one surface 51. As shown in FIG. 7, in the deposition method according to the present embodiment, a deposition step (first step) S1, a determination step S2, a gap widening step (second step) S3, a movement step (third step) S4, and a gap reducing step (fourth step) S5 are sequentially performed.

(Deposition Step S1 with Respect to the k-th Active Area Column)

First, as shown in FIG. 9, the relative position of the substrate 50 and the deposition mask 120 are fixed, and one deposited pattern column is formed on the one surface 51 of the substrate 50. FIG. 9 shows an example in which a deposited pattern is formed with respect to the k-th column, active column 52ₖ (k=1 to t−1). While the deposition is being performed, the relative position between the deposition mask 120 and the substrate 50 is fixed. The size of the gap 141 between the deposition mask 120 and the substrate 50 is set to be sufficiently small. This enables suppression of blurring of the edges of the deposited pattern.

When the deposition with respect to the k-th column, active area column 52ₖ, is started, the deposition source 150 is positioned at a first position 150p. At the time at which the deposition with respect to the active area column 52ₖ is started, the shutter 260 is pulled out from the space between the deposition mask 120 and the deposition source 150. This opens up the ejection paths from the deposition source 150 that reach the apertures 121 of the deposition mask 120. As a result, the deposition of the k-th column, active area column 52ₖ, starts.

During the deposition with respect to the k-th column, active area column 52ₖ, the second moving apparatus 280 (refer to FIG. 8) causes parallel reciprocating movement of the deposition source 150 with respect to the substrate 50 in the scanning direction SD, in the region from the first position 150p to the second position 150q.

In the present embodiment as well, during deposition, the deposition source 150 moves relatively with respect to the substrate 50.

As a result, during deposition with respect to the k-th column, active area column 52ₖ, deposition particles are deposited from a various directions, from the first position 150p until reaching the second position 150q. As a result, the film thickness variation is suppressed, and it is possible to make the film thickness uniform.

When the deposition with respect to the k-th column, active area column 52ₖ, ends, the shutter 260 is inserted into the space between the deposition mask 120, and the deposition source 150 positioned at the first position 150p. This closes the ejection paths from the deposition source 150 to the apertures 121 of the deposition mask 120. As a result, the deposition step (first step) S1 with respect to the k-th column, active area column 52ₖ, ends.

(Determination Step S2)

As shown in FIG. 7, at the point at which the deposition step S1 ends, if the formation of the deposited pattern columns with respect to the all from the first to the t-th column, the active area columns 52ₖ (k=1 to t) has been completed, the entire deposition process is ended. If that is not the case, processing proceeds to the gap widening step S3.

(Gap Widening Step S3)

Next, as shown in FIG. 10, the gap adjustment apparatus 240 (refer to FIG. 8) spaces apart the deposition mask 120 and the substrate 50. At the point at which the gap 141 between the deposition mask 120 and the substrate 50 has become sufficiently large, the gap adjustment apparatus 240 stops the relative movement between the deposition mask 120 and the substrate 50. By setting a sufficiently large gap 141, it is possible to prevent contact between the deposition mask 120 and the substrate 50 during the time in which the deposition mask 120 is moving relative to the substrate 50 in the scanning direction in the movement step S4, which will be described later.

(Movement Step S4)

Next, as shown in FIG. 11, the first moving apparatus 230 (refer to FIG. 8) causes movement of the substrate 50 relative to the deposition mask 120, in the direction opposite from the scanning direction SD, from the position at which the apertures 121 are opposite to the k-th column, active area column 52ₖ, to the position at which they are opposite the (k+1)th column, active area column 52ₖ₊₁. When the deposition mask 120 reaches the position at which the apertures 121 are opposite the (k+1)th column, active area column 52ₖ₊₁, the first moving apparatus 230 stops the relative movement between the deposition mask 120 and the substrate 50.

(Gap Reducing Step S5)

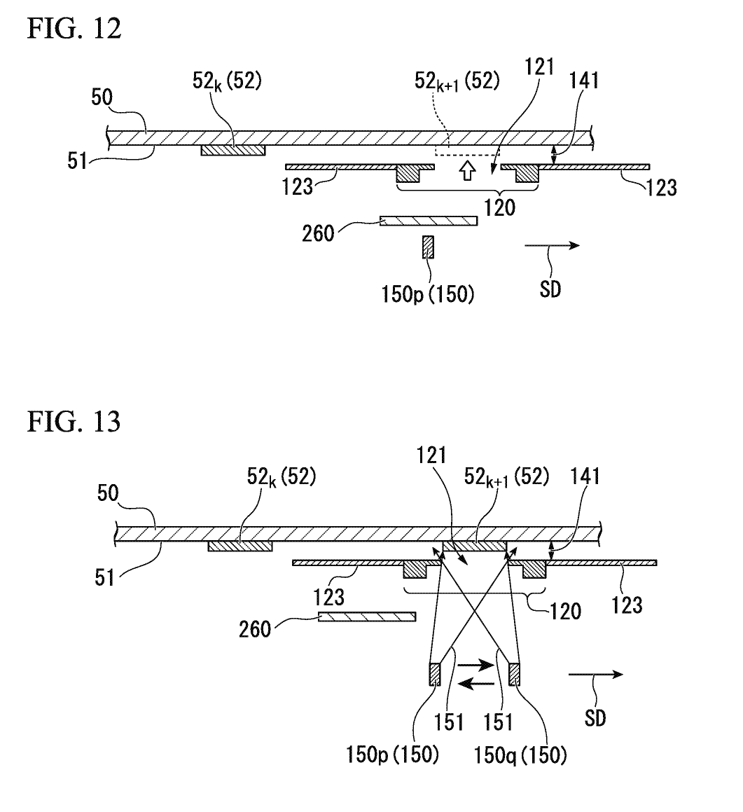

Next, as shown in FIG. 12, the gap adjustment apparatus 240 (refer to FIG. 8) causes the deposition mask 120 and the substrate 50 to come into mutual proximity At the point at which the gap 141 between the deposition mask 120 and the substrate 50 has become sufficiently small, the gap adjustment apparatus 240 stops the relative movement between the deposition mask 120 and the substrate 50. By setting the gap 141 sufficiently small, it is possible to suppress blurring of the edges of the deposited pattern.

(Deposition Step 51 with Respect to the (k+1)th Active Area Column)

Next, as shown in FIG. 13, deposition is performed with respect to the (k+1)th column, active area column 52ₖ₊₁. At the time the deposition with respect to the (k+1)th column, active area column 52ₖ₊₁, starts, the deposition source 150 is positioned at the first position 105p. At the time the deposition with respect to the (k+1)th column, active area column 52ₖ₊₁, starts, the shutter 260 is pulled out from the space between the deposition mask 120 and the deposition source 150. This opens up the ejection paths from the deposition source 150 that reach the apertures 121 of the deposition mask 120. As a result, the deposition of the (k+1)th column, active area column 52ₖ₊₁, starts.

During the deposition with respect to the (k+1)th column, active area column 52ₖ₊₁, the second moving apparatus 280 (refer to FIG. 8) causes reciprocating movement of the deposition source 150 with respect to the substrate 50, in the region from the first position 150p to the second position 150q, parallel to the scanning direction.

After that, in the same manner, deposition is performed from the 1st column, active area column 52₁, to the t-th column, active area column 52ₜ. This completes the deposition of the entire region of the active area group 52.

The second embodiment is described above. Although in the above-described deposition step S1, the deposition source 150 moves reciprocally between the first position 150p and the second position 105q, this is not a restriction. For example, when deposition is performed with respect to the k-th active area column 52ₖ (where k is an odd number), the deposition source 150 may be moved in the scanning direction SD from the first position 150p to the second position 150q, and when deposition is performed with respect to the k-th active area column 52ₖ (where k is an even number), the deposition source 150 may be moved in the direction opposite to the scanning direction SD from the second position 150q to the first position 150p, thereby enabling a shortening of the deposition time, while maintaining uniformity of the film thickness equivalent to that of the first embodiment.

In the present embodiment, while deposition is being done, the temperature control means 170 may be used to lower the temperature of the deposition source 150. This enables suppression of unnecessary consumption of material.

Although preferred embodiments of the present invention have been described above with reference to the drawings, the present invention is not restricted to those examples. The shapes, and combinations and the like of the constituent elements in the above-described examples are exemplary, and can be variously modified, based on design requirements, within the scope of the spirit of the present invention.

### INDUSTRIAL APPLICABILITY

An aspect of the present invention can be applied to a deposition apparatus and the like which is required to suppress film thickness variation and suppress blurring of deposited patterns.

### DESCRIPTION OF THE REFERENCE SYMBOLS

100, 200 Deposition mask
110 Substrate holder
120 Deposition mask
121 Aperture
130, 230 First moving apparatus
140, 240 Gap adjustment apparatus
141 Gap
150 Deposition source
151 Ejection path
160, 260 Shutter
170 Temperature control means
180, 280 Second moving apparatus
50 Substrate
51 One surface
S1 First step
S3 Second step
S4 Third step
S5 Fourth step

1. A deposition apparatus comprising:
a substrate holder configured to hold a substrate;
a deposition mask configured to be disposed on one surface side of the substrate;
a first moving apparatus configured to cause first relative movement by a stepwise change in a relative position between the deposition mask and the substrate in a first direction parallel to the one surface in a condition in which the deposition mask and the substrate are spaced apart from each other;
a gap adjustment apparatus configured to, before a start of the first relative movement between the deposition mask and the substrate by the first moving apparatus, cause second relative movement between the deposition mask and the substrate in a second direction spacing the deposition mask and the substrate apart and adjusts a gap between the deposition mask and the substrate, and when the first moving apparatus has stopped the second relative movement between the deposition mask and the substrate, cause third relative movement between the deposition mask and the substrate in a third direction in which the deposition mask and the substrate approach each other and adjust the gap between the deposition mask and the substrate; and
a deposition source configured to, after the gap adjustment apparatus causes the third relative movement and adjusts the gap supply deposition particles to the one surface of the substrate, through an aperture provided in the deposition mask, to form a film of the deposited particles on the one surface exposed from the aperture.

2. The deposition apparatus according to claim 1, the deposition apparatus comprising:
a shutter configured to, when the deposition mask and the substrate are in the first relative movement by the first moving apparatus, and when the gap is being adjusted by the gap adjustment apparatus, block ejection paths of the deposition particles from the deposition source heading to the aperture.

3. The deposition apparatus according to claim 2, the deposition apparatus comprising:
a temperature controlling means configured to lower a deposition temperature of the deposition source when the ejection paths are blocked by the shutter.

4. The deposition apparatus according to claim 1, the deposition apparatus comprising:
a second moving apparatus configured to, when the deposition source is supplying the deposition particles to the one surface through the aperture, cause fourth relative movement between the deposition source and the substrate in a fourth direction parallel to the one surface.

5. The deposition apparatus according to claim 4,
wherein the second moving apparatus is configured to cause the fourth relative movement so that the deposition source is reciprocally moved when viewed from the substrate.

6. The deposition apparatus according to claim 1,
wherein the gap adjustment apparatus is configured to rotate the deposition mask about a rotational axis perpendicular to the one surface to align the deposition mask with respect to the substrate.

7. A deposition method that, by disposing a deposition mask on one surface side of a substrate and, by depositing deposition particles on the one surface through a deposition mask while changing, in a stepped manner, a relative position between the deposition mask and the substrate in a first direction parallel to the one surface, sequentially forms a plurality of deposited pattern columns on the one surface, the deposition method comprising:
fixing the relative position, supplying the deposition particles to the one surface through an aperture provided in the deposition mask from a deposition source to form one deposited pattern column on the one surface;
causing, after completing the fixing of the relative position, first relative movement between the deposition mask and the substrate in a second direction that spaces the deposition mask and the substrate apart to adjust a gap between the deposition mask and the substrate;
causing second relative movement by changing the relative position in the first direction in a condition in which the deposition mask and the substrate are spaced apart each other; and
causing, when the second relative movement has stopped, third relative movement between the deposition mask and the substrate in a third direction in which the deposition mask and the substrate approach each other to adjust the gap.

8. The deposition method according to claim 7,
wherein, while performing the first to third relative movements, ejection paths of the deposition particles from the deposition source heading to the aperture provided in the deposition mask are blocked.

9. The deposition method according to claim 8,
wherein the deposition temperature of the deposition source is lowered while the ejection paths are blocked.

10. The deposition method according to claim 7,
wherein, while performing the fixing of the relative position, fourth relative movement is caused between the deposition source and the substrate in a fourth direction parallel to the one surface.

11. The deposition method according to claim 10,
wherein the fourth relative movement is performed so that the deposition source is reciprocally moved when viewed from the substrate.

12. The deposition method according to claim 7,
wherein, while performing the third relative movement, the deposition mask is rotated about a rotational axis perpendicular to the one surface to align the deposition mask with respect to the substrate.

13. The deposition apparatus according to claim 1, the deposition apparatus comprising:
a second moving apparatus configured to move relatively the deposition source and the substrate in a fourth direction parallel to the one surface while the deposition mask and the substrate space apart or approach each other.

14. The deposition apparatus according to claim 13, the deposition apparatus comprising:
a shutter configured to be moved relatively tracking to the deposition source so that the ejection paths from the deposition source to the aperture of the deposition mask continue to be blocked, the movement of the shutter being performed while the deposition mask and the substrate space apart or approach each other.

15. The deposition apparatus according to claim 1, the deposition apparatus comprising:
a second moving apparatus configured to move relatively the deposition source and the substrate in a fourth direction parallel to the one surface while the deposition mask and the substrate move relatively in a fifth direction parallel to the one surface.

16. The deposition apparatus according to claim 1, wherein
the first moving apparatus is configured to cause the first relative movement by fixing a position of the substrate and by moving the position of the substrate, and
the deposition source is configured to be reciprocally moved only in a vicinity of positions opposing the aperture.

17. The deposition apparatus according to claim 16, wherein
a length of a shutter in the first direction is a length that covers one column within an active area group of the substrate.

18. An organic EL display formed by the deposition method according to claim 7.
